(19) United States
(12) Patent Application Publication
(10) Pub. No.: US 2012/0327108 A1
(43) Pub. Date: Dec. 27, 2012

(54) IMAGE DISPLAY APPARATUS, IMAGE DISPLAY CIRCUIT, AND IMAGE DISPLAY METHOD

(75) Inventors: Toshiyuki Kato, Osaka (JP); Takahiro Kobayashi, Okayama (JP); Hiroshi Mitani, Osaka (JP)

(73) Assignee: Panasonic Corporation, Osaka (JP)

(21) Appl. No.: 13/517,227

(22) PCT Filed: Dec. 22, 2010
(86) PCT No.: PCT/JP2010/007432

§ 371 Date: Jun. 19, 2012

(30) Foreign Application Priority Data
Dec. 24, 2009 (JP) 2009-291708

(51) Int. Cl. G09G 5/00; G09G 5/39

(52) U.S. Cl. 345/619; 345/531; 345/211

(57) ABSTRACT

An image display apparatus and an image display method are provided by which a total length of light-emission duration for each display line can be increased. An image display apparatus for displaying an image includes: display lines which form a display screen and each of which displays tone information of display data; a first gate driver which sequentially write the display data into first storage capacitors provided in respective pixel circuits; a third gate driver which writes the display data written in the first storage capacitors, into corresponding second storage capacitors provided in the respective pixel circuits; and organic EL elements which emit light based on the display data written in the corresponding second storage capacitors, and within a period during which the display lines emit light by the organic EL elements, the first gate driver writes display data of a next image into the first storage capacitors.

### TECHNICAL FIELD

The present invention relates to an image display apparatus and an image display circuit which display images alternately, such as a stereoscopic image display apparatus of a time-division shutter type, and also relates to an image display method which is used in the image display apparatus and the image display circuit.

### BACKGROUND ART

A stereoscopic image display apparatus of what is called a time-division shutter type is widely available in various fields including a medical field and an entertainment field. The stereoscopic image display apparatus displays a right-eye image and a left-eye image alternately. A user can view stereoscopic images by viewing images of the stereoscopic image display apparatus through a pair of glasses with a shutting mechanism (hereinafter referred to as “shutter”) that alternately blocks the field of vision for a right eye and the field of vision for a left eye in synchronization with switching of image display (which glasses are hereinafter referred to as “shutter glasses”).

However, it takes a certain length of time for switching of the shutter between an open state and a closed state (hereinafter referred to as “shutter switching”). In a period of time from the start to the end of the shutter switching (hereinafter referred to as “shutter switching period”), light can enter both eyes. In the shutter switching period, when a right-eye image is displayed, the right-eye image goes to the left eye as well, and when a left-eye image is displayed, the left-eye image goes to the right eye as well. In other words, crosstalk between the right-eye image and the left-eye image occurs, which causes a failure to display high-quality stereoscopic images.

Thus, a technique of preventing crosstalk between a right-eye image and a left-eye image is disclosed by PTL 1, for example.

FIG. 7 is an operation timing chart of a stereoscopic image display apparatus disclosed by PTL 1. FIG. 7 shows, in (a), starting and ending points in time for light-emitting operation (hereinafter referred to as “light emission”) based on the display data of each display line. FIG. 7 shows, in (b), open and closed states of a right-eye shutter at respective points in time. FIG. 7 shows, in (c), open and closed states of a left-eye shutter at respective points in time.

A panel of the stereoscopic image display apparatus includes 1080 display lines vertically arranged in parallel, for example. Each of the display lines includes a plurality of pixels horizontally arranged in a linear fashion, for example. As shown in (a) of FIG. 7, the stereoscopic image display apparatus sequentially performs scanning and writing for the respective display lines of the display data, so as to cause each of the display lines to emit light immediately after the writing of the display data for the display line is completed, and stops the light emission after a lapse of a certain length of time.

Meanwhile, at a first point in time t1 at which the stop operations for light emission of all the display lines are completed, the stereoscopic image display apparatus outputs to the shutter glasses a control signal to instruct the shutter glasses to switch the right-eye shutter from an open state to a shut state and to switch the left-eye shutter from a shut state to an open state. From a second point in time t2 at which the shutter switching of the shutter glasses is completed, the stereoscopic image display apparatus starts to scan and write the display data of a next left-eye image and starts to emit light. Thus, in a shutter switching period Sc from the first point in time t1 to the second point in time t2, no images are displayed.

Subsequently, at a third point in time t3 at which the stop operations for light emission of all the display lines are completed, the stereoscopic image display apparatus outputs a control signal to instruct the shutter glasses to switch the left-eye shutter from the open state to a shut state and to switch the right-eye shutter from the shut state to an open state. Afterward, the stereoscopic image display apparatus starts to scan and write the display data of a right-eye image and starts to emit light at a fourth point in time t4 after the shutter switching period Sc.

Through the operation as above, the period in which light for a right-eye image is emitted, the period in which light for a left-eye image is emitted, and the shutter switching period Sc are arranged so as not to overlap in time axis, with the result that crosstalk between the right-eye image and the left-eye image can be prevented.

### CITATION LIST

### Patent Literature

[PTL 1] Japanese Unexamined Patent Application Publication No. 62-061493
[PTL 2] Japanese Unexamined Patent Application Publication No. 2003-066908

### SUMMARY OF INVENTION

### Technical Problem

However, the stereoscopic image display apparatus disclosed by PTL 1 has a problem of difficulty in displaying a bright image. The reason is as follows.

To start scanning and writing on all the display lines and to start light emission of all the display lines, it takes a predetermined time Ton in relation to the display data. Furthermore, to stop the light emission of all the display lines, it takes a predetermined time Toff which is substantially the same in length as Ton because the display lines have the same light emission duration in principle. Accordingly, maximum light emission duration Td for each of the display lines is represented by Expression 1 as below in relation to the shutter switching period Sc and a frame cycle f in which a right-eye image and a left-eye image which constitute one frame are displayed.

Td=f/2−Sc−Ton (Expression 1)

This means that the maximum light emission duration for each of the right and left eyes in one cycle can last only within a range obtained by subtracting, from half the length of the frame cycle f, the shutter switching period Sc and the time Ton required to start scanning and writing on all the display lines and start light emission of all the display lines. In addition, it is difficult to increase the length of the frame cycle f in order that the images do not appear to blink.

To provide a brighter image, the conceivable approaches are to increase the total length of light-emission duration and to increase the luminance of each pixel during the light emission. However, in the case of the stereoscopic image display apparatus disclosed by PTL 1, the total length of light-emission duration cannot be greater than the value represented by Expression 1 indicated above, which leaves only the option of increasing the luminance of each pixel, in order to further increase the luminance of the image. An increase in the luminance of a pixel will, however, cause problems of an increase in power load along with a decrease in operating life of a light-emitting element.

Thus, in order to obtain a brighter image, an increase in the total length of light-emission duration is beneficial.

Furthermore, the above-described problems sometimes occur not only in a stereoscopic image display apparatus, but also in a two-dimensional display apparatus which displays two-dimensional images. For example, suppose a two-dimensional display apparatus in which light is emitted from an entire screen after line-sequential writing in one frame for movement of moving pictures. In the case of this two-dimensional display apparatus, the light emission period has a length of time determined by subtracting a length of time for writing of one frame from the length of time assigned to one frame. In short, the length of the light emission period decreases as the length of time for writing of one frame increases in the case of the two-dimensional display apparatus.

The present invention has been devised in view of the above and has an object to provide an image display apparatus, an image display circuit, and an image display method with which the total display period for each of the display lines can be longer.

### Solution to Problem

In order to achieve the above object, an image display apparatus according to an aspect of the present invention is an image display apparatus which displays an image corresponding to received display data, the image display apparatus comprising: a plurality of display lines which form a display screen and each of which displays tone information included in the display data; a first scanning and writing unit configured to sequentially write the display data into first storage units provided in each of the display lines; a second scanning and writing unit configured to write the display data written in the first storage units, into corresponding second storage units provided in each of the display lines; and amount-of-light adjusting units configured to adjust amounts of light of the display lines based on the display data written in the second storage units, wherein within a period during which at least a part of the display lines continuously displays the tone information according to a corresponding one or ones of the amount-of-light adjusting units, the first scanning and writing unit is configured to write display data of a next image into a corresponding one or ones of the first storage units in the at least a part of display lines.

With the above structure, (i) preparatory writing-line scanning in which the display data are sequentially written into the first storage unit and (ii) light emission caused by main writing-line scanning in which the display data written in the first storage unit are written into the second storage unit, are controlled independently, with the result that the preparatory scanning and writing of next display data can be performed on the display line which is in operation to display an image with a given tone. By so doing, the total length of light-emission duration in a frame can be greater, so that a bright image can be displayed.

Furthermore, it may be possible that the image display apparatus receives the display data of left-eye and right-eye images which form a stereoscopic image, and alternately displays the left-eye image and the right-eye image on the display screen, and within a period during which at least a part of the display lines continuously displays the tone information of one of the left-eye image and the right-eye image according to a corresponding one or ones of the amount-of-light adjusting units, the first scanning and writing unit is configured to write the display data of the other of the left-eye image and the right-eye image into a corresponding one or ones of the first storage units.

By so doing, the total length of light-emission duration in a frame can be greater, so that a bright stereoscopic image can be displayed. In other words, it becomes possible to provide a stereoscopic image display apparatus of a time-division shutter type which provides bright images with high reliability over long periods of time.

Furthermore, it may be possible that the amount-of-light adjusting units include light-emitting elements which cause the display lines to continuously emit light, based on the tone information of the display data written in the second storage units, and within a period during which at least a part of the display lines continuously emits light by a corresponding one or ones of the light-emitting elements, the first scanning and writing unit is configured to write display data of a next image into a corresponding one or ones of the first storage units in the at least a part of display lines.

This makes it possible to apply the present invention to the image display apparatus which includes a current-driving light-emitting element.

Furthermore, it is desirable that time required for the second scanning and writing unit to complete the writing into all the second storage units in the display lines be shorter than time required for the first scanning and writing unit to complete the writing into all the first storage units in the display lines.

With this, the total length of light-emission duration in one frame period can be greater.

Furthermore, it is desirable that the image display apparatus further include a shutting-timing control unit configured to control timing of switching of a shutter state of a pair of glasses capable of alternately blocking a field of vision for a left eye and a field of vision for a right eye, and the display lines avoid the continuous display during a period in which the shutter state of the glasses is switched.

With this, the period in which light for the right-eye image is emitted, the period in which light for the left-eye image is emitted, and the shutter switching period are arranged so as not to overlap in time axis, with the result that crosstalk between the right-eye image and the left-eye image can be prevented.

Furthermore, the second scanning and writing unit may be configured to simultaneously perform the writing into all the second storage units in the display lines so that the continuous display of the display lines according to the amount-of-light adjusting units starts simultaneously.

Furthermore, it may be possible that the image display apparatus further include a light-emission stopping unit configured to stop the continuous light-emission of the display lines, and the light-emission stopping unit be configured to simultaneously stop the continuous light-emission of the display lines.

With this, the total length of light-emission duration in one frame period can be set to be as long as possible.

Furthermore, the light-emission stopping unit may be configured to reset the data written in the second storage units in the display lines, to stop the continuous light-emission of the display lines.

This makes it possible to provide a function of stopping the light emission of the light-emitting element and at the same time, reset the potential held in the second storage unit to predetermined potential.

Furthermore, each of the light-emitting elements may be an organic electroluminescence (EL) element.

Furthermore, each of the light-emitting elements may be an inorganic electroluminescence (EL) element.

Furthermore, each of the light-emitting elements may be a light-emitting diode.

Furthermore, at least one of the first scanning and writing unit, the second scanning and writing unit, and the light-emission stopping unit may be an element included in a current programming circuit.

Furthermore, at least one of the first scanning and writing unit, the second scanning and writing unit, and the light-emission stopping unit may be an element included in a voltage programming circuit.

Furthermore, at least one of the first scanning and writing unit, the second scanning and writing unit, and the light-emission stopping unit may be an element included in a clamped inverter circuit.

Furthermore, the present invention can be implemented not only as the image display apparatus which has the features described as above, but also as the image display circuit implementing such image display apparatus, which produces the same or like effects as those described above.

Moreover, the present invention can be implemented not only as the image display apparatus which includes characteristic constituents described as above, but also as the image display method which includes, as steps, the characteristic constituents included in the image display apparatus.

### Advantageous Effects of Invention

According to the present invention, the writing of next image display data can be performed on the display line during a period in which the display line continuously displays the tone information of display data, with the result that the total length of display time for each of the display lines can be greater.

### BRIEF DESCRIPTION OF DRAWINGS

FIG. 1 is a block diagram showing an example of a structure of an image display apparatus according to an embodiment of the present invention.

FIG. 2 is a circuit diagram showing an example of a structure of an organic EL pixel circuit in the embodiment.

FIG. 3 is an operation timing chart of the image display apparatus according to the embodiment of the present invention.

FIG. 4 is an operation timing chart of an image display apparatus according to a first variation of the embodiment of the present invention.

FIG. 5 is an operation timing chart of an image display apparatus according to a second variation of the embodiment of the present invention.

FIG. 6 is a circuit diagram showing an example of a structure of a pixel circuit which uses a voltage-driving element according to the present invention.

FIG. 7 is an operation timing chart of a conventional image display apparatus.

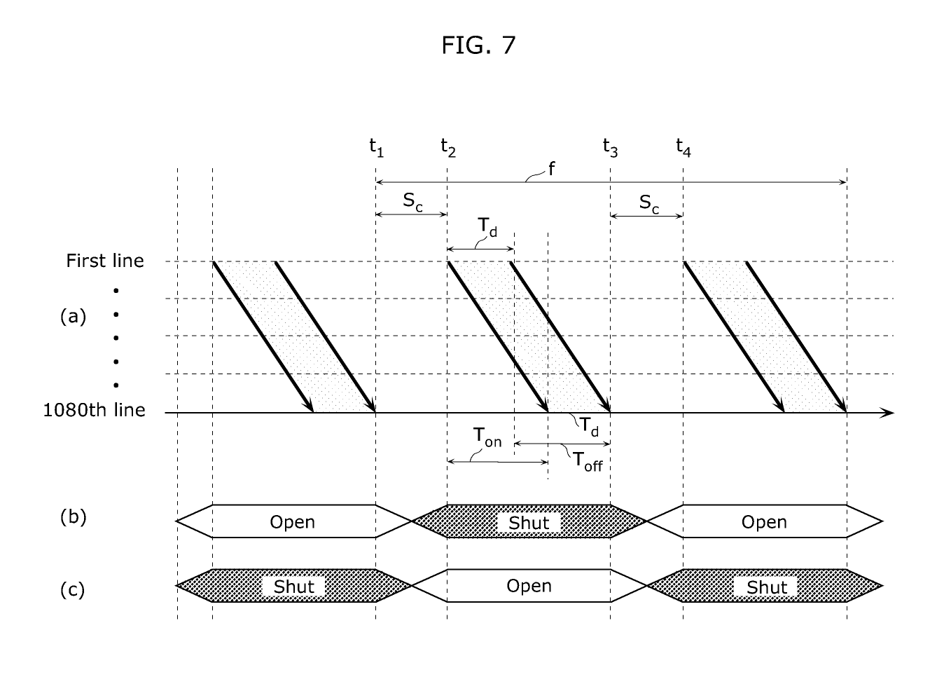

### DESCRIPTION OF EMBODIMENTS

Embodiments of the present invention are described below with reference to the drawings.

This embodiment is an example where the present invention is applied to a stereoscopic image display apparatus which uses an organic electroluminescence (EL) element as a light-emitting element and is used together with a pair of shutter glasses which alternately block the field of vision for a right eye and the field of vision for a left eye in synchronization with switching of image display.

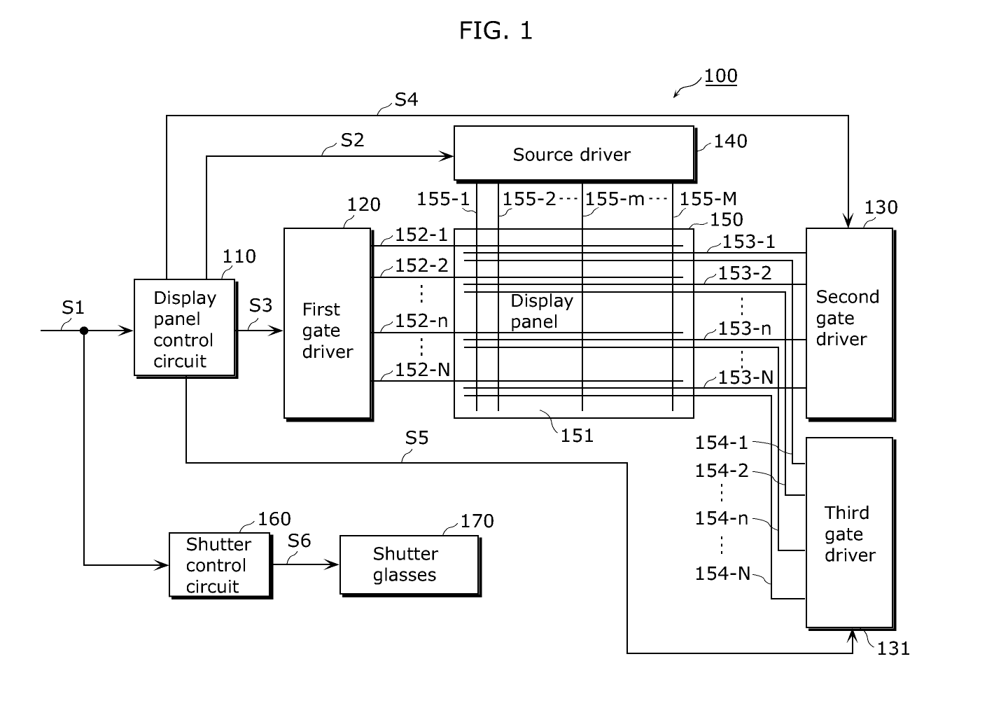

FIG. 1 is a block diagram showing a structure of an image display apparatus according to an embodiment of the present invention.

In FIG. 1, an image display apparatus 100 includes a display panel control circuit 110, a first gate driver 120, a second gate driver 130, a third gate driver 131, a source driver 140, a display panel 150, a shutter control circuit 160, and a pair of shutter glasses 170.

The display panel 150 is an organic EL panel and includes a display region 151 as a display screen. Furthermore, the display panel 150 includes N first writing lines 152-1, 152-2, . . . , and 152-N, N reset control lines 153-1, 153-2, . . . , 153-N, and N second writing lines 154-1, 154-2, . . . , 154-N, all of which are arranged in parallel with one another where N is, for example, 1080, and M source signal lines 155-1, 155-2, . . . , 155-M which are arranged perpendicularly to these first writing lines 152, the reset control lines 153, and the second writing lines 154. Moreover, in the display panel 150, an organic EL pixel circuit (not shown) including a thin-film transistor and an organic EL diode is provided at each cross-point of the source signal line 155 and the first writing line 152. Hereinafter, a group of organic EL pixel circuits which correspond to a single first writing line 152 or second writing line 154 will be referred to “display line” as appropriate. In other words, the display panel 150 is composed of N display lines each of which has M organic EL diodes.

The display panel control circuit 110 generates a source-driver control signal S2 based on a display data signal S1 and outputs the generated source-driver control signal S2 to the source driver 140. Furthermore, the display panel control circuit 110 generates, based on a received synchronization signal, a first-gate-driver control signal S3, a second-gate-driver control signal S4, and a third-gate-driver control signal S5. The display panel control circuit 110 then outputs the generated first-gate-driver control signal S3 to the first gate driver 120, outputs the generated second-gate-driver control signal S4 to the second gate driver 130, and outputs the generated third-gate-driver control signal S5 to the third gate driver 131.

The display data signal S1 is a signal indicating display data which includes a video signal, a vertical synchronization signal, and a horizontal synchronization signal. The video signal is a signal designating, on a per frame basis, tone information, i.e., each pixel value of a left-eye image and each pixel value of a right-eye image. The vertical synchronization signal is a signal for synchronizing the timing of processing in the vertical direction on the screen and is herein a signal which serves as a criterion for the timing of per-frame processing on each of a left-eye image and a right-eye image. The horizontal synchronization signal is a signal for synchronizing the timing of processing in the horizontal direction on the screen and is herein a signal which servers as a criterion for the timing of per-display-line processing.

The first-gate-driver control signal S3, the second-gate-driver control signal S4, and the third-gate-driver control signal S5 each include the vertical synchronization signal and the horizontal synchronization signal. The source-driver control signal S2 includes the video signal and the horizontal synchronization signal.

The source driver 140 drives the source signal lines 155-1 to 155-M of the display panel 150 based on the source-driver control signal S2 generated by the display panel control circuit 110. More specifically, the source driver 140 outputs a source signal to each of the organic EL pixel circuits based on the video signal and the horizontal synchronization signal.

The first gate driver 120 is a first scanning and writing unit of the display panel 150 and drives the first writing lines 152-1 to 152-N of the display panel 150 based on the first-gate-driver control signal S3 generated by the display panel control circuit 110. More specifically, the first gate driver 120 outputs, based on the vertical synchronization signal and the horizontal synchronization signal, a preparatory-writing signal to each of the organic EL pixel circuits at least per display line.

The second gate driver 130 is a light-emission stopping unit of the display panel 150 and drives the reset control lines 153-1 to 153-N of the display panel 150 based on the second-gate-driver control signal S4 generated by the display panel control circuit 110. More specifically, the second gate driver 130 outputs, based on the vertical synchronization signal and the horizontal synchronization signal, a reset control signal to each of the organic EL pixel circuits at least per display line.

The third gate driver 131 is a second scanning and writing unit of the display panel 150 and drives the second writing lines 154-1 to 154-N of the display panel 150 based on the third-gate-driver control signal S5 generated by the display panel control circuit 110. More specifically, the third gate driver 131 outputs, based on the vertical synchronization signal and the horizontal synchronization signal, a main-writing signal to each of the organic EL pixel circuits at least per display line.

The display panel control circuit 110 described above controls the signals such that the first gate driver 120 first performs preparatory scanning and writing on the first writing line 152-n where n is an integer of 1 to N. Afterward, the display panel control circuit 110 controls the signals such that the third gate driver 131 performs main scanning and writing on the second writing line 154-n after the reset control line 153-n is scanned and reset by the second gate driver 130. By so doing, an image corresponding to the display data is displayed in the display region 151 of the display panel 150.

The shutter control circuit 160 generates, based on the display data signal S1, a shutter control signal S6 for instructing the shutter glasses 170 to switch the shutters. The shutter control circuit 160 then transmits the generated shutter control signal S6 to the shutter glasses 170, for example, via infrared communication. In other words, the shutter control circuit 160 is a shutting-timing control unit which controls the timing of switching of a shutter state of a pair of glasses capable of alternately blocking the field of vision for a right eye and the field of vision for a left eye.

The shutter glasses 170 are, for example, a pair of glasses with liquid crystal shutters in lens parts for both eyes. Specifically, the shutter glasses 170 switch the shutter states of right and left lenses according to the shutter control signal S6 so that video displayed by the display panel 150 alternately enters a right eye and a left eye.

Furthermore, the image display apparatus 100 includes, although not shown, a central processing unit (CPU), a storage medium such as a read only memory (ROM) in which a control program is stored, a working memory such as a random access memory (RAM), and a communication circuit, for example. Thus, the display data signal 51 is generated, for example, by the execution of the control program by the CPU. Furthermore, the source driver 140, the first gate driver 120, the second gate driver 130, the third gate driver 131, and the shutter control circuit 160 are components included in a current programming circuit, a voltage programming circuit, or a clamped inverter circuit of a light-emission-period control type.

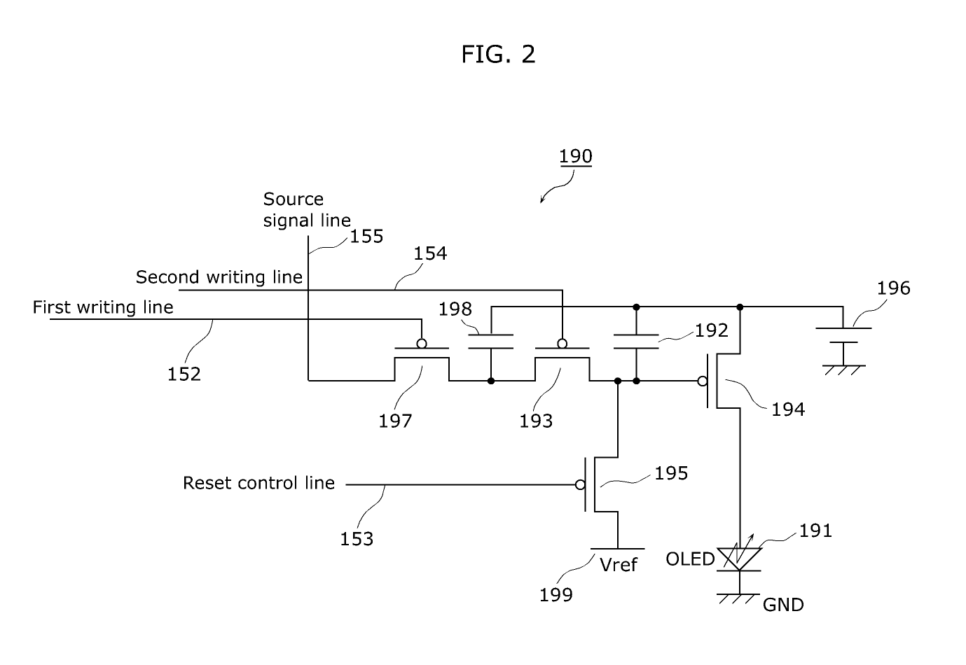

FIG. 2 is a circuit diagram showing an example of a structure of the organic EL pixel circuit in the image display apparatus.

In FIG. 2, an organic EL pixel circuit 190 is an image display circuit which includes an organic light emitting diode (OLED) 191, a first storage capacitor 198, a second storage capacitor 192, a preparatory-writing transistor 197, a data writing transistor 193, a tone control transistor 194, and a reset control transistor 195.

The first storage capacitor 198 is an example of a component included in a first storage unit and corresponds to a first storage element, and the second storage capacitor 192 is an example of a component included in a second storage unit and corresponds to a second storage element.

The preparatory-writing transistor 197 is a first switching element and allows electrical conduction between the source signal line 155 and the first storage capacitor 198 according to the preparatory-writing signal provided by the first gate driver 120 through the first writing line 152. With the preparatory-writing transistor 197 placed in the conducting state, the first gate driver 120 writes a first voltage corresponding to potential of the source signal provided through the source signal line 155, into the first storage capacitor 198 connected to a drive-voltage source 196.

Furthermore, the data writing transistor 193 is a second switching element and allows electrical conduction between the first storage capacitor 198 and the second storage capacitor 192 according to the main-writing signal provided by the third gate driver 131 through the second writing line 154. With the data writing transistor 193 placed in the conducting state, the third gate driver 131 writes a second voltage corresponding to the first voltage held in the first storage capacitor 198, into the second storage capacitor 192 connected to the drive-voltage source 196.

Here, the writing of the first voltage into the first storage capacitor 198 by the preparatory-writing transistor 197 needs to be performed by sequentially scanning the display lines according to the source signals. On the other hand, the writing of the second voltage into the second storage capacitor 192 by the data writing transistor 193 does not need to be performed by sequentially scanning the display lines because the potential already written in the first storage capacitor 198 is written. Thus, the time required for the writing from the first storage capacitors to the second storage capacitors 192 in all the display lines can be shorter than the time required for the writing into the first storage capacitors 198 in all the display lines.

The tone control transistor 194 is a driving element of which gate-source voltage is the second voltage held in the second storage capacitor 192 and which converts the second voltage into a drive current which is a drain current.

The organic EL diode 191 is a light-emitting element which, when a drain current flows in the tone control transistor 194, emits light according to such drain current. In other words, the tone control transistor 194 and the organic EL diode 191 function as an amount-of-light adjusting unit which adjusts an amount of light in each of the display lines based on the second voltage written in the second storage capacitor 192, that is, based on the display data. The above structure allows the plurality of display lines forming the display screen to display, for each line and in a short period of time, the tone information included in the display data.

The reset control transistor 195 is disposed between the gate of the tone control transistor 194 and a reference voltage source 199. The reset control transistor 195 allows electrical conduction between the gate of the tone control transistor 194 and the reference voltage source 199 according to the reset control signal outputted from the second gate driver 130 to the reset control line 153. With the reset control transistor 195 placed in the conducting state, the gate potential of the tone control transistor 194 is reset to a reference voltage, which places the tone control transistor 194 in the OFF state. By so doing, the reset control transistor 195 drives the organic EL diode 191, that is, performs a switching operation for light emission. Furthermore, the reset control transistor 195 receives the above-mentioned reset control signal and thereby resets, to predetermined potential, the potential held in the second storage capacitor 192. With this, in writing into the second storage capacitor 192 the second voltage corresponding to the first voltage held in the first storage capacitor 198, the second voltage to be written into the second storage capacitor 192 is determined according to the first voltage held in the first storage capacitor 198. In short, the reset control transistor 195 has a function of stopping the light emission of the organic EL diode 191 and at the same time, a function of resetting the potential held in the second storage capacitor 192 to predetermined potential.

The organic EL pixel circuit 190 configured as above is capable of independently executing a scanning process of sequential writing from the source signal line to the first storage capacitor 198 per display line, and a process of setting a writing tone from the first storage capacitor 198 to the second storage capacitor 192.

This means that the organic EL pixel circuit 190 is, for example, capable of providing, for each of the display lines, a temporal difference between an ending point in time of the preparatory scanning and writing in which display data of a corresponding part of an image is written into the first storage capacitor and a starting point in time of the main scanning and writing in which the display data is written into the second storage capacitor. It is therefore possible to perform the preparatory scanning and writing for the first storage capacitor according to next display data while maintaining, at a certain value, a drive current of the tone control transistor 194 that controls the tone according to potential of the second storage capacitor 192. In other words, the first scanning and writing unit is capable of writing, in one of the display lines, next display data into the first storage capacitor within a period in which the organic EL diode 191 continues to emit light.

Specifically, in this embodiment, the image display apparatus 100 stops light emission according to the reset control signal at a start of the shutter switching period, starts light emission by performing a process of setting a writing tone from the first storage capacitor to the second storage capacitor as soon as possible after an end of the shutter switching period, and continues the light emission until a next shutter switching period starts. By so doing, a period other than the shutter switching period is used as much as possible to emit light. Furthermore, in a period from the start of the light emission to the end of the next shutter switching period, the preparatory scanning and writing process of writing the first voltage into the first storage capacitor starts. By so doing, the writing of the potential of the source signal can be performed during a continuous light-emission period. It is therefore possible to efficiently prepare for the start of next continuous light emission and thereby possible to start to emit light immediately after the end of the shutter switching period.

An example of the operation of the image display apparatus 100 in which the light emission, each writing, and switching of the shutters are controlled as above is described.

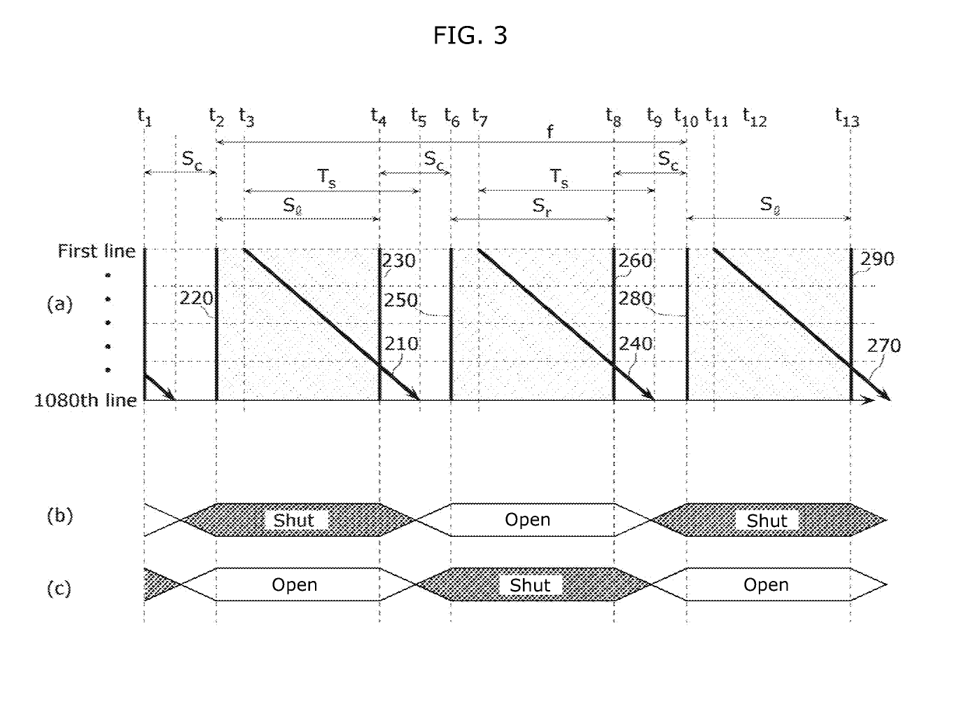

FIG. 3 is an operation timing chart of the image display apparatus according to this embodiment. FIG. 3 shows, in (a), starting and ending points in time of light emission of the display lines. FIG. 3 shows, in (b), open and closed states of a right-eye shutter at respective points in time. FIG. 3 shows, in (c), open and closed states of a left-eye shutter at respective points in time.

As shown in (b) and (c) of FIG. 3, the image display apparatus 100 causes, at a point in time t1, the shutter glasses 170 to switch the right-eye shutter from an open state to a shut state and to switch the left-eye shutter from a shut state to an open state.

Meanwhile, immediately after a point in time t2 at which the shutter switching period Sc ends, the image display apparatus 100 starts light emission simultaneously from all the display lines as shown by a line 220 and displays a left-eye image. Subsequently, at a third point in time t3, the first gate driver 120 starts the preparatory writing of the display data of a next right-eye image on the initial display line as shown by a line 210. This processing corresponds to a first scanning and writing step of sequentially writing, by the first scanning and writing unit, the display data into the first storage unit for the plurality of display lines.

In other words, the plurality of display lines do not continue to emit light during the shutter switching period Sc in which the shutter state of the glasses is switched.

After a displayable period Sl for the left-eye image ends and immediately before t4 at which the shutter switching period Sc starts, the image display apparatus 100 performs scanning and resetting on all the display lines as shown by a line 230, thereby stopping the light emission. The preparatory writing shown by the line 210 is completed at a point in time t5 that is in the shutter switching period Sc.

Subsequently, immediately after a point in time t6 at which the shutter switching period Sc ends, the third gate driver 131 writes, for all the display lines, the second voltage from the first storage capacitor into the second storage capacitor swiftly as shown by a line 250, thereby causing all the display lines to emit light. By so doing, the right-eye image is displayed while only the right-eye shutter of the shutter glasses 170 is in a light-transmissive state. The above processing corresponds to: a second scanning and writing step of writing, by the second scanning and writing unit, the display data written in the first storage units, into the corresponding second storage units provided in each of the display lines; and a displaying step of continuously displaying, in the display lines, the tone information of the display data written in the second storage units, according to the amount-of-light adjusting units.

Through the above steps, the first scanning and writing unit starts the writing of display data of a next image into the first storage unit while the plurality of display lines continuously display the tone information according to the amount-of-light adjusting unit.

Particularly, in the above second scanning and writing step, the second scanning and writing unit performs all the writing into the second storage unit in the plurality of display lines simultaneously so that the continuous display of the plurality of display lines according to the amount-of-light adjusting unit starts simultaneously.

Subsequently, at a point in time t7, the first gate driver 120 starts the preparatory writing of the display data of a next left-eye image on the initial display line as shown by a line 240. After a displayable period Sr for the right-eye image ends and immediately before a point in time t8 at which the shutter switching period Sc starts, the image display apparatus 100 performs scanning and resetting on all the display lines as shown by a line 260, thereby stopping the light emission. The preparatory writing shown by the line 240 is completed at a point in time t9 that is in the shutter switching period Sc.

Subsequently, immediately after a point in time t10 at which the shutter switching period Sc ends, the third gate driver 131 writes, for all the display lines, the second voltage from the first storage capacitor into the second storage capacitor swiftly as shown by a line 280, thereby causing all the display lines to emit light. By so doing, the left-eye image is displayed while only the left-eye shutter of the shutter glasses 170 is in a light-transmissive state.

The image display apparatus 100 afterwards repeats, in the same manner, the preparatory scanning and writing, the operation to stop the display through the scanning and resetting, the shutter switching, and the operation to start the display of the display data through the main scanning and writing.

As a result, a state where the left-eye image enters only the left eye of a user and a state where the right-eye image enters only the right eye of the user are alternately repeated in the frame cycle f which is so short that the switching of the states is not recognized.

For example, for a set of a right-eye image and a left-eye image which constitute one frame, the frame cycle f is 16 milliseconds (ms), the shutter switching period Sc is 2 ms, and each of the displayable period Sl for the left-eye image and the displayable period Sr for the right-eye image is 6 ms. In such a short frame cycle f, the switching between display and non-display of an image and the switching of images are not recognized. Thus, a stereoscopic image is displayed by the above operation.

As described above, according to this embodiment, the preparatory writing-line scanning and the light emission caused by the main writing-line scanning can be independently controlled, with the result that the preparatory scanning and writing of next display data can be performed even during the light emission with a given tone. By so doing, the total length of light-emission duration in a frame can be greater, so that a bright stereoscopic image can be displayed. In other words, it becomes possible to provide a stereoscopic image display apparatus of a time-division shutter type which provides bright images with high reliability over long periods of time.

It is to be noted that although this embodiment describes an example in which the end of the preparatory writing by the first gate driver 120 serving as the first scanning and writing unit is in the shutter switching period Sc, the present invention is not limited to this example.

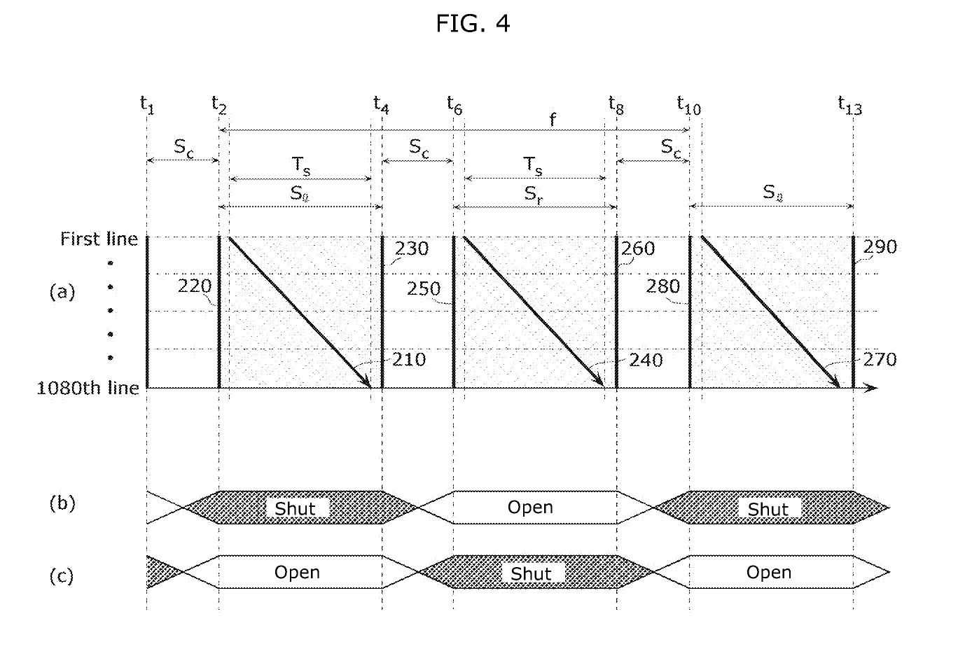

FIG. 4 is an operation timing chart of an image display apparatus according to a first variation of the embodiment of the present invention. For example, as shown in FIG. 4, the end of the preparatory writing by the first gate driver 120 may be in the continuous light-emission period. When the preparatory writing is performed in at least a part of the plurality of display lines within the continuous light-emission period, the total length of light-emission duration can be greater than that in a conventional example.

Furthermore, although this embodiment describes an example in which the main writing by the third gate driver 131 serving as the second scanning and writing unit is simultaneously performed in all the display lines, the present invention is not limited to this example.

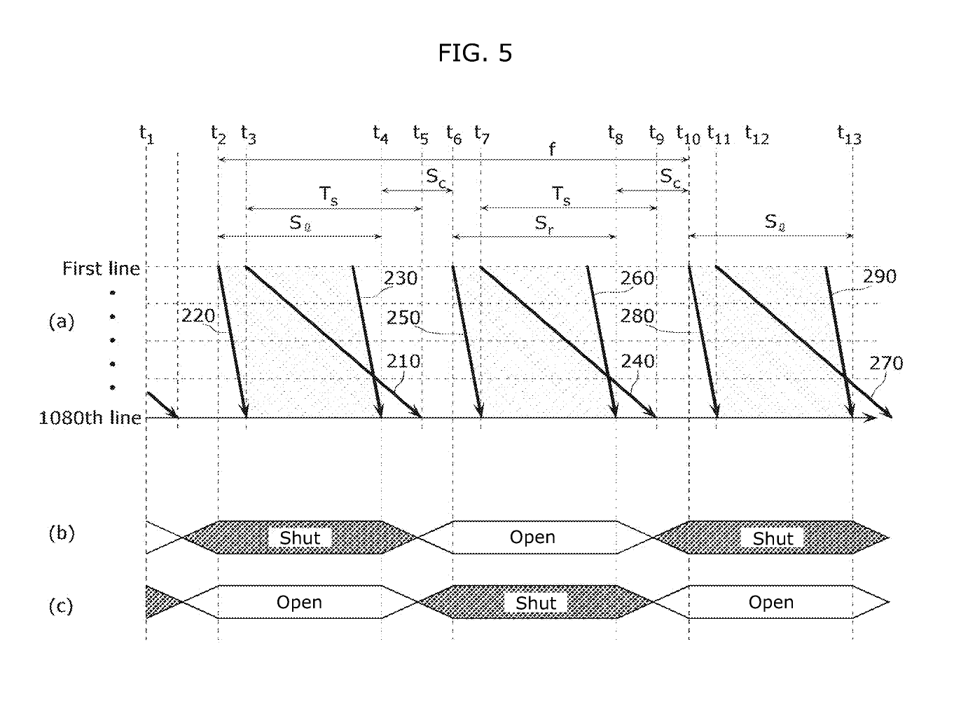

FIG. 5 is an operation timing chart of an image display apparatus according to a second variation of the embodiment of the present invention. For example, as shown in FIG. 5, the writing may be sequentially performed in the respective display lines to emit light. Alternatively, it may be possible that the simultaneous writing is performed on a part of the display lines while the sequential writing is performed on the other part of the display lines. In the case where light is simultaneously emitted by the simultaneous writing, the power load on a power source, a driver, or the like will temporarily increase. In contrast, the sequential main writing performed as shown in FIG. 5 allows a reduction in the power load by distributing power consumption. At this time, when the time required for the third gate driver 131 to complete all the writing in the plurality of display lines is shorter than the time required for the first gate driver 120 to complete all the writing in the plurality of display lines, the total length of light-emission duration can be greater than that in a conventional example.

Furthermore, as long as time Ts required for the preparatory scanning and writing using the source signal line 155 is in a range less than half the length of the frame cycle f, the entire time other than the shutter switching period can be used to emit light. Thus, even when a low-cost, low power consuming source driver with a slow scanning speed is used, it is possible to maximize the period in which a left-eye image and a right-eye image can be displayed.

It is to be noted that although the embodiment and variations thereof described above show examples in which a right-eye image and a left-eye image which form a stereoscopic image are alternately displayed, the present invention is not limited to these examples. The present invention is also applicable to other image display apparatus in which display and non-display of an image are alternately repeated in a screen composed of a plurality of display lines.

For example, the present invention is applicable to an image display apparatus which displays, to a plurality of users, different images for the respective users. In this case, it is sufficient that the image display apparatus switches shutter states of plural pairs of shutter glasses 170 in synchronization with switching of display of images. This allows the plurality of users wearing the respective pairs of shutter glasses 170 to independently select content to be viewed, i.e., video, games, and so on, using a single display.

Furthermore, also in a two-dimensional display apparatus which displays a two-dimensional image, the apparatus structure and display method described in the embodiments can increase a luminance of each pixel by increasing the total length of light-emission duration. Specifically, even in the case where the displayable period Sr for the right-eye image and the displayable period Sl for the left-eye image which are described in the above embodiment are replaced by a continuous image display period, and the shutter switching period Sc described in the above embodiment is replaced by a black insertion period, it is possible to increase the total length of light-emission duration and thereby increase a luminance of each pixel while ensuring visibility of moving pictures, when, within a period during which at least a part of the plurality of display lines continuously displays the tone information according to a corresponding one or ones of the amount-of-light adjusting units, the first scanning and writing unit writes display data of an image into a corresponding one or ones of the first storage units in the at least a part of plurality of display lines.

Furthermore, in the case of displaying moving pictures, there is such a disadvantage that images of frames different in an upper screen part and a lower screen part are simultaneously viewed depending on the relationship between a moving speed of the moving pictures and a speed of sequential scanning on the display lines. In the case where the present invention is applied as a two-dimensional display apparatus, the writing into the second storage units, which is included in the sequential scanning on the display lines and relates to the display operation, is performed in all the lines at a time, with the result that there is no such a disadvantage of moving pictures that images of frames different in an upper screen part and a lower screen part are simultaneously viewed.

Furthermore, the case in which an organic EL panel is used has been described, but the present invention is not limited to this case. For example, the present invention is applicable to an image display apparatus in which the scanning and writing of display data and the light-emission duration can be independently controlled, among other various image display apparatuses which use light-emitting elements such as inorganic EL elements and light-emitting diodes.

Furthermore, the present invention is not limited to the image display apparatus which uses current-driving light-emitting elements represented by organic EL elements, and is also applied to an image display apparatus which uses a liquid crystal panel and voltage-driving light-emitting elements such as micro electro mechanical systems (MEMS), which produces the same or like effects.

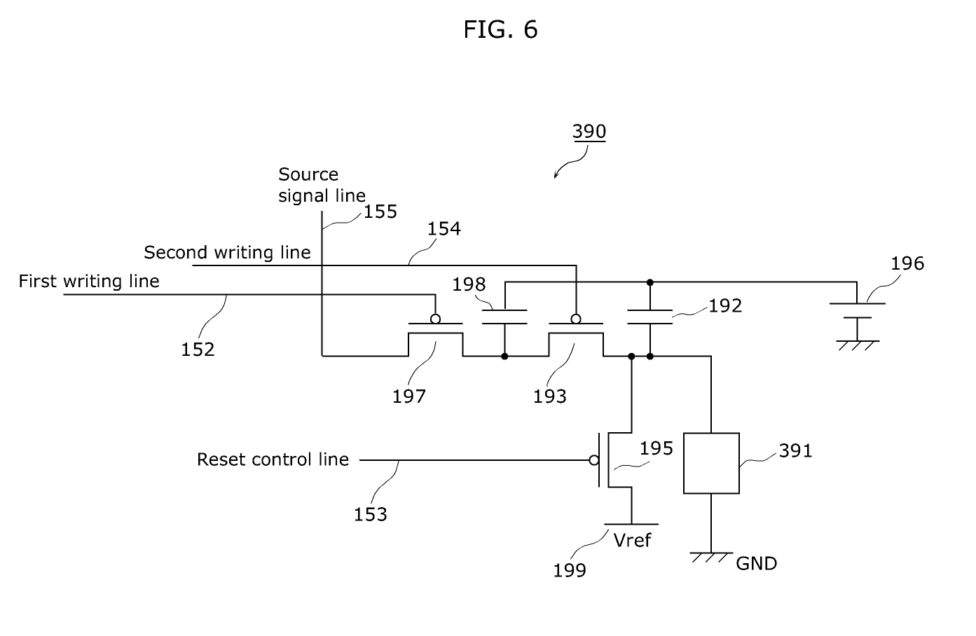

FIG. 6 is a circuit diagram showing an example of a structure of a pixel circuit which uses a voltage-driving element according to the present invention. In this figure, a voltage-driving pixel circuit 390 includes the first storage capacitor 198, the second storage capacitor 192, the preparatory-writing transistor 197, the data writing transistor 193, the reset control transistor 195, and an amount-of-light adjusting element 391. The voltage-driving pixel circuit 390 is different from the organic EL pixel circuit 190 described in the embodiment in that the amount-of-light adjusting element 391 is provided instead of the organic EL element 191 and the tone control transistor 194. Only the features different from those of the organic EL pixel circuit 190 are described hereinbelow, omitting the descriptions on the features the same as those of the organic EL pixel circuit 190.

The amount-of-light adjusting element 391 has a function of adjusting, according to the second voltage stored in the second storage capacitor 192, an amount of light of a display element, such as a backlight, which serves as a light source.

Within a period during which at least a part of the plurality of display lines continuously displays the tone information according to a corresponding one or ones of the amount-of-light adjusting units 391, the first gate driver 120 then writes display data of an image into a corresponding one or ones of the first storage units 198 in the at least a part of plurality of display lines. Here, the period during which the tone information is continuously displayed according to the amount-of-light elements 391 corresponds to the periods Sl and Sr in the timing charts of FIGS. 3 to 5.

The voltage-driving pixel circuit 390 configured as above is capable of independently executing a scanning process of sequential writing from the source signal line to the first storage capacitor 198 per display line, and a process of setting a writing tone from the first storage capacitor 198 to the second storage capacitor 192. By so doing, also in this structure, the total length of light-emission duration in a frame can be greater, so that a bright image can be displayed. In other words, it becomes possible to provide an image display apparatus which provides bright images with high reliability over long periods of time.

Although the image display apparatus, the image display circuit, and the image display method according to the present invention have been described above based on the embodiments, the image display apparatus, the image display circuit, and the image display method according to the present invention are not limited to those in the above-described embodiments. The present invention includes variations that can be obtained by making, to the embodiments, various modifications that are conceivable to a person of ordinary skill in the art without departing from the essence of the present invention, and various devices internally equipped with the image display apparatus and the image display circuit according to the present invention.

### INDUSTRIAL APPLICABILITY

The image display apparatus, the image display circuit, and the image display method according to the present invention are useful as an image display apparatus, an image display circuit, and an image display method by which the total length of light-emission duration for each display line can be increased.

### REFERENCE SIGNS LIST

100 Image display apparatus
110 Display panel control circuit
120 First gate driver
130 Second gate driver
131 Third gate driver
140 Source driver
150 Display panel
151 Display region
152 First writing line
153 Reset control line
154 Second writing line
155 Source signal line
160 Shutter control circuit
170 Shutter glasses
190 Organic EL pixel circuit
191 Organic EL diode
192 Second storage capacitor
193 Data writing transistor
194 Tone control transistor
195 Reset control transistor
196 Drive-voltage source
197 Preparatory-writing transistor
198 First storage capacitor
199 Reference voltage source
210, 220, 230, 240, 250, 260, 280 Lines
390 Voltage-driving pixel circuit
391 Amount-of-light adjusting element

1. An image display apparatus which displays an image corresponding to received display data, said image display apparatus comprising:
a plurality of display lines which form a display screen and each of which displays tone information included in the display data;
a first scanning and writing unit configured to sequentially write the display data into first storage units provided in each of said display lines;
a second scanning and writing unit configured to write the display data written in said first storage units, into corresponding second storage units provided in each of said display lines; and
amount-of-light adjusting units configured to adjust amounts of light of said display lines based on the display data written in said second storage units,
wherein within a period during which at least a part of said display lines continuously displays the tone information according to a corresponding one or ones of said amount-of-light adjusting units, said first scanning and writing unit is configured to write display data of a next image into a corresponding one or ones of said first storage units in said at least a part of display lines.

2. The image display apparatus according to claim 1,
wherein said image display apparatus receives the display data of left-eye and right-eye images which form a stereoscopic image, and alternately displays the left-eye image and the right-eye image on the display screen, and
within a period during which at least a part of said display lines continuously displays the tone information of one of the left-eye image and the right-eye image according to a corresponding one or ones of said amount-of-light adjusting units, said first scanning and writing unit is configured to write the display data of the other of the left-eye image and the right-eye image into a corresponding one or ones of said first storage units.

3. The image display apparatus according to claim 1,
wherein said amount-of-light adjusting units include light-emitting elements which cause said display lines to continuously emit light, based on the tone information of the display data written in said second storage units, and
within a period during which at least a part of said display lines continuously emits light by a corresponding one or ones of said light-emitting elements, said first scanning and writing unit is configured to write display data of a next image into a corresponding one or ones of said first storage units in said at least a part of display lines.

4. The image display apparatus according to claim 1,
wherein time required for said second scanning and writing unit to complete the writing into all said second storage units in said display lines is shorter than time required for said first scanning and writing unit to complete the writing into all said first storage units in said display lines.

5. The image display apparatus according to claim 2, further comprising
a shutting-timing control unit configured to control timing of switching of a shutter state of a pair of glasses capable of alternately blocking a field of vision for a left eye and a field of vision for a right eye,
wherein said display lines avoid the continuous display during a period in which the shutter state of the glasses is switched.

6. The image display apparatus according to claim 1,
wherein said second scanning and writing unit is configured to simultaneously perform the writing into all said second storage units in said display lines so that the continuous display of said display lines according to said amount-of-light adjusting units starts simultaneously.

7. The image display apparatus according to claim 3, further comprising
a light-emission stopping unit configured to stop the continuous light-emission of said display lines,
wherein said light-emission stopping unit is configured to simultaneously stop the continuous light-emission of said display lines.

8. The image display apparatus according to claim 3, further comprising
a light-emission stopping unit configured to stop the continuous light-emission of said display lines,
wherein said light-emission stopping unit is configured to reset the data written in said second storage units in said display lines, to stop the continuous light-emission of said display lines.

9. The image display apparatus according to claim 3,
wherein each of said light-emitting elements is an organic electroluminescence (EL) element.

10. The image display apparatus according to claim 3,
wherein each of said light-emitting elements is an inorganic electroluminescence (EL) element.

11. The image display apparatus according to claim 3,
wherein each of said light-emitting elements is a light-emitting diode.

12. The image display apparatus according to claim 3, further comprising
a light-emission stopping unit configured to stop the continuous light-emission of said display lines,
wherein at least one of said first scanning and writing unit, said second scanning and writing unit, and said light-emission stopping unit is an element included in a current programming circuit.

13. The image display apparatus according to claim 3, further comprising
a light-emission stopping unit configured to stop the continuous light-emission of said display lines,
wherein at least one of said first scanning and writing unit, said second scanning and writing unit, and said light-emission stopping unit is an element included in a voltage programming circuit.

14. The image display apparatus according to claim 3, further comprising
a light-emission stopping unit configured to stop the continuous light-emission of said display lines,
wherein at least one of said first scanning and writing unit, said second scanning and writing unit, and said light-emission stopping unit is an element included in a clamped inverter circuit.

15. An image display circuit comprising:
a first storage element in which a first voltage corresponding to a display data signal supplied through a source signal line is stored;
a second storage element in which a second voltage corresponding to the first voltage stored in said first storage element is stored;
a first switching element which switches between conduction and non-conduction between the source signal line and said first storage element;
a second switching element which switches between conduction and non-conduction between said first storage element and said second storage element;
a driving element which converts the second voltage stored in said second storage element, into a drive current corresponding to the second voltage; and
a light-emitting element which emits light according to the drive current when the drive current flows in said light-emitting element.

16. An image display circuit comprising:
a first storage element in which a first voltage corresponding to a display data signal supplied through a source signal line is stored;
a second storage element in which a second voltage corresponding to the first voltage stored in said first storage element is stored;
a first switching element which switches between conduction and non-conduction between the source signal line and said first storage element;
a second switching element which switches between conduction and non-conduction between said first storage element and said second storage element; and
an amount-of-light adjusting element which adjusts an amount of light of a display element according to the second voltage stored in said second storage element.

17. An image display method performed by an image display apparatus which displays an image corresponding to received display data, said image display method comprising:
sequentially writing the display data into first storage units provided in each of a plurality of display lines which displays tone information included in the display data;
writing the display data written in the first storage units, into corresponding second storage units provided in each of the display lines; and
continuously displaying, in the display lines, the tone information of the display data written in the second storage units, according to amount-of-light adjusting units which adjust amounts of light of the display lines,
wherein in said continuously displaying, within a period during which at least a part of the display lines continuously displays the tone information according to a corresponding one or ones of the amount-of-light adjusting units, writing of display data of a next image into a corresponding one or ones of the first storage units in the at least a part of display lines starts.

18. The image display method according to claim 17,
wherein in said writing, the writing into all the second storage units in the display lines is simultaneously performed so that the continuous display of the display lines according to the amount-of-light adjusting units starts simultaneously.
